(19) United States
(12) Patent Application Publication
(10) Pub. No.: US 2017/0234816 A1
(43) Pub. Date: Aug. 17, 2017

(54) TEMPERATURE SENSOR BASED ON DIRECT THRESHOLD-VOLTAGE SENSING FOR ON-CHIP DENSE THERMAL MONITORING

(71) Applicant: The Trustees Of Columbia University In The City Of New York, New York, NY (US)

(72) Inventors: Mingoo Seok, New York, NY (US); Seongjong Kim, New York, NY (US)

(21) Appl. No.: 15/239,085

(22) Filed: Aug. 17, 2016

Related U.S. Application Data
(60) Provisional application No. 62/207,130, filed on Aug. 19, 2015.

(51) Int. Cl. G01N 25/00; G01K 1/14; G11C 27/02

(52) U.S. Cl. CPC G01N 25/00; G11C 27/026; G01K 1/14

(57) ABSTRACT

Systems and methods for measuring a temperature dependency of a threshold voltage are provided. Disclosed systems can include a shared pre-charge P-type metal-oxide-semiconductor (PMOS) transister, configured to pre-charge an output node to a supply voltage. The system can further include a sensing PMOS transistor, electrically coupled to the shared pre-charge PMOS transistor, configured to discharge the output node to a first voltage at or near the threshold voltage of the sensing PMOS transistor and measure a second voltage at the output node.

### CROSS REFERENCE TO RELATED APPLICATION

This application claims priority to U.S. Provisional Application No. 62/159,821, filed on Aug. 19, 2015, which is incorporated by reference herein in its entirety.

### STATEMENT REGARDING FEDERALLY-SPONSORED RESEARCH

This invention was made with government support from the Defense Advanced Research Projects Agency under Grant No. HR0011-13-C-0003. The government has certain rights in the invention.

### BACKGROUND

Dynamic thermal management is a topic within the field of digital very-large-scale integration (VLSI) systems. On-chip temperature sensors can be used for dense thermal monitoring in digital VLSI systems. The number and accuracy of sensors on a chip can impact the performance and efficiency of dynamic thermal management.

In contrast to certain existing sensors, a smaller and more accurate (e.g., ±3° C.) sensor can offer improved hot-spot detection, dynamic thermal-map generation, and power estimation, while also providing improved design flexibility and impact on a floor-plan. Additionally, a sensor with voltage-scalability down to near-threshold regime (e.g., 0.4-0.6V) can be integrated with digital circuits using sub-1V voltages without additional voltage distribution and/or local regulation. Accordingly, there is a need for on-chip temperature sensors that are smaller, more accurate, and more voltage-scalable.

### SUMMARY

In a first aspect of the present disclosure, systems for measuring a temperature dependency of a threshold voltage are provided. An example system can include a shared pre-charge P-type metal-oxide-semiconductor (PMOS) transistor, configured to pre-charge an output node to a supply voltage. The system can further include a sensing PMOS transistor, electrically coupled to the shared pre-charge PMOS transistor, and configured to discharge the output node to a first voltage at or near the threshold voltage of the sensing PMOS transistor. The system can also measure a second voltage at the output node.

Another exemplary system can include a shared pre-charge P-type metal-oxide-semiconductor (PMOS) transistor, configured to pre-charge an output node to a supply voltage. The system can further include an array of sensing PMOS transistors, electrically coupled to the shared pre-charge PMOS transistor, and configured to discharge the output node to a first voltage at or near the threshold voltage of the sensing PMOS transistor and measure a second voltage at the output node.

In some embodiments, the system can further include a sample and hold circuit, electrically coupled to the shared pre-charge PMOS transistor and the array of sensing PMOS transistors, and can be configured to measure a third voltage at the output node. The system can further include an analog-to-digital convertor, and can be configured to digitize the third voltage.

In some embodiments, the sensing PMOS transistor can be configured to enter a weak inversion region once the sensing PMOS transistor discharges the output node to the first voltage. A gate source voltage of the sensing PMOS transistor can be configured to be set at or near the threshold voltage. The sensing PMOS transistor can be configured to measure the second voltage at a time after the sensing PMOS transistor discharges the output node.

The present disclosure also provides methods for measuring a temperature dependency of a threshold voltage. An example method can include pre-charging an output node to a supply voltage using a shared pre-charge P-type metal-oxide-semiconductor (PMOS) transistor. The method can further include measuring a second voltage at the output node, using a sensing PMOS transistor, by discharging the output node to a first voltage at or near the threshold voltage of the sensing PMOS transistor.

In some embodiments, the method can further include measuring a third voltage at the output node using a sample and hold circuit. The method can further include digitizing the third voltage using an analog-to-digital converter.

In some embodiments, the sensing PMOS transistor can enter a weak inversion region upon the discharging the output node. The measuring a second voltage can be at a time after the discharging the output node.

In some embodiments, the method can further include setting a gate source voltage of the sensing PMOS transistor at or near the threshold voltage.

### BRIEF DESCRIPTION OF THE DRAWINGS

FIG. 1(a) illustrates a circuit diagram of an exemplary on-chip temperature sensor, in accordance with one or more embodiments.

FIG. 1(b) illustrates a graph showing operation of an exemplary on-chip temperature sensor, in accordance with one or more embodiments.

FIG. 2 illustrates a graph showing a relationship between threshold voltage and temperature, in accordance with one or more embodiments.

FIG. 3(a) illustrates a graph showing a linearity of the sampled voltage at the sensory output node across time, in accordance with one or more embodiments.

FIG. 3(b) illustrates a graph showing a discharge rate of the sampled voltage at the sensory output node across time, in accordance with one or more embodiments.

FIG. 4 illustrates a graph showing an effect of sampling voltage at the sensory output node at a time after the time when the sensing PMOS transistor enters the weak inversion region, in accordance with one or more embodiments.

FIG. 5 illustrates a circuit diagram of another exemplary on-chip temperature sensor, in accordance with one or more embodiments.

FIG. 6(a) illustrates a graph showing measurements results of 3σerrors of multiply combined on-chip temperature sensors, in accordance with one or more embodiments.

FIG. 6(b) illustrates a graph showing measurements results of output voltage from dies including on-chip temperature sensors after temperature point calibration, in accordance with one or more embodiments.

FIG. 6(c) illustrates a graph showing measurements results of errors of dies including on-chip temperature sensors after temperature point calibration, in accordance with one or more embodiments.

FIG. 7(a) illustrates a graph showing measurements results of errors of dies including on-chip temperature sensors after temperature point calibration, in accordance with one or more embodiments.

FIG. 7(b) illustrates a graph showing measurements results of worst-case errors of dies including on-chip temperature sensors across supply voltage after temperature point calibration, in accordance with one or more embodiments.

FIG. 7(c) illustrates a graph showing measurements results of worst-case errors of dies including on-chip temperature sensors across time, in accordance with one or more embodiments.

FIG. 8 illustrates an exemplary table showing robustness results, in accordance with one or more embodiments.

FIG. 9 illustrates a graph showing robustness results, in accordance with one or more embodiments.

FIG. 10 illustrates an exemplary diagram of a die including on-chip temperature sensors, in accordance with one or more embodiments.

### DETAILED DESCRIPTION

The present disclosure provides systems and methods for measuring a temperature dependency of a threshold voltage. Accordingly, the techniques described herein can pre-charge an output node to a supply voltage using a shared pre-charge P-type metal-oxide-semiconductor (PMOS) transistor. The techniques can further include measuring a second voltage at the output node, using a sensing PMOS transistor, by discharging the output node to a first voltage at or near the threshold voltage of the sensing PMOS transistor.

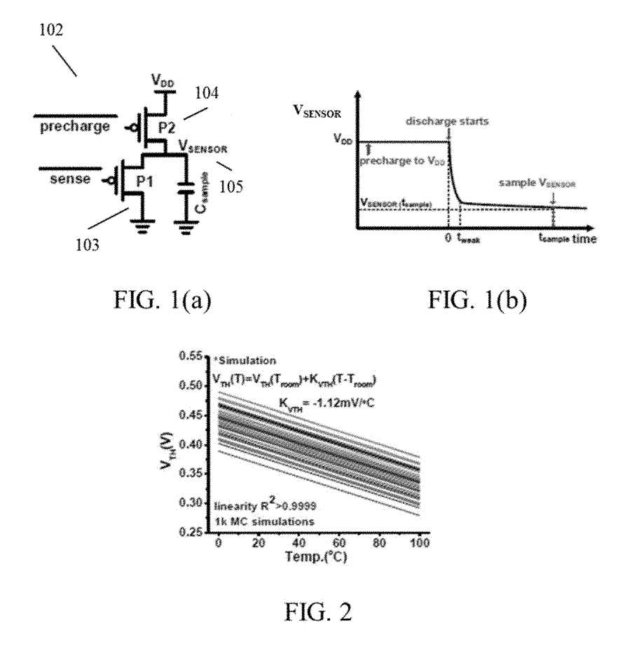

FIG. 1(a) illustrates a circuit diagram of an exemplary on-chip temperature sensor 102. As illustrated by the example embodiment depicted in FIG. 1(a), on-chip temperature sensor 102 can include a sensing P-type metal-oxide-semiconductor (PMOS) transistor 103 (P1). The on-chip temperature sensor 102 can also include a shared pre-charge PMOS transistor 104 (P2) electrically coupled and/or connected (e.g., by electrical wire) to the sensing PMOS transistor 103 (P1).

FIG. 1(b) illustrates a graph showing operation of the exemplary on-chip temperature sensor 102 of FIG. 1(a). As shown in a waveform depicted in FIG. 1(b) for the purpose of illustration and not limitation, P2 can be turned on to pre-charge a sensory output (V_{SENSOR}) node 105 located in the temperature sensor circuit at the connection point of the drain teiminal of P1 with the drain terminal of P2. Once the sensory output node 105 is pre-charged to a supply voltage (V_{DD}), P2 can be turned off and P1 can be turned on to discharge the sensory output node 105 to a voltage level at or near a threshold voltage (V_{TH}) of P1. For example, V_{TH} of P1 can be from about 0.2 V to about 0.7 V. At t_{weak} as shown in FIG. 1(b) for the purpose of illustration and not limitation, P1 can enter a weak inversion region, and a discharge rate of P1 can be reduced. At tₛₐₘₚₗₑ as shown in FIG. 1(b) for the purpose of illustration and not limitation, V_{SENSOR} can then be sampled.

The exemplary on-chip temperature sensor 102 of FIG. 1(a) can measure a temperature dependency of V_{TH} by utilizing a linear relationship between V_{TH} and temperature. FIG. 2 illustrates a graph showing a relationship between threshold voltage and temperature. As shown in FIG. 2 for the purpose of illustration and not limitation, simulation using the Simulation Program with Integrated Circuit Emphasis (SPICE) can show that V_{TH} curve over temperature has a linearity of R²>0.9999. Manufacturing process variations can modulate the offset of the V_{TH} curve and thus can be calibrated via one temperature point calibration (OPC). As such, temperature information can be accurately extracted by measuring V_{TH}.

In the exemplary on-chip temperature sensor 102 of FIG. 1, V_{SENSOR} can be sampled at an appropriate time to have, for example, a) good linearity of sampled V_{SENSOR} over temperature; b) robustness against a leakage current of P1; c) robustness of a temperature coefficient (TC) of sampled V_{SENSOR} against process variation; and d) robustness against pre-charge level variation.

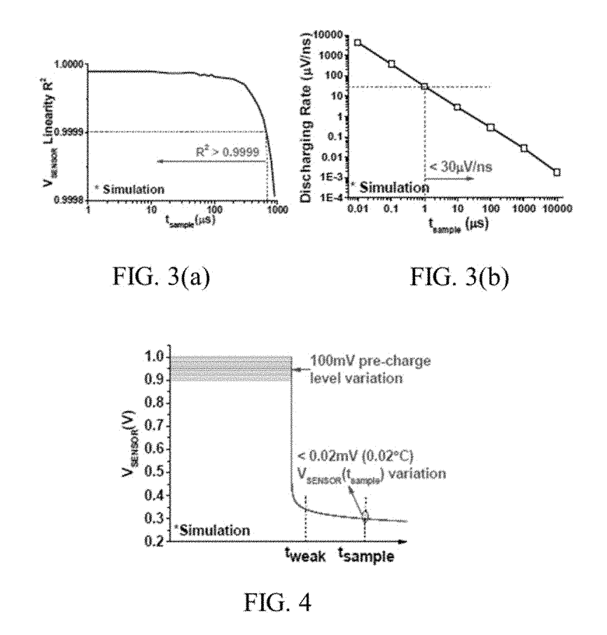

The appropriate time of sampling V_{SENSOR} can be determined based on linearity and leakage constraints. FIG. 3(a) illustrates a graph showing a linearity of the sampled voltage at the sensory output node across time. As shown in FIG. 3(a.) for the purpose of illustration and not limitation, the linearity of sampled V_{SENSOR} can rapidly degrade after 700 μs after P1 is turned on.

FIG. 3(b) illustrates a graph showing a discharge rate of the sampled voltage at the sensory output node across time. As shown in FIG. 3(b) for the purpose of illustration and not limitation, if tₛₐₘₚₗₑ is small (e.g., <1 μs), the discharge rate of P1 can perturb the potential of sampled V_{SENSOR}. As such, the appropriate time of sampling V_{SENSOR} can be from about 1 μs to about 700 μs after P1 is turned on.

The dependency of V_{SENSOR} on temperature when a transistor enters the weak inversion region can be represented as:

$${V}_{SENSOR} ( {t}_{sample} ) = {V}_{TH} - \frac{{I}_{weak} \cdot ( {t}_{sample} - {t}_{weak} )}{{C}_{sample}} , \qquad ( 1 )$$

where tₛₐₘₚₗₑ (the time to sample V_{SENSOR}) can be more than 10× larger than t_{weak} (the time when P1 enters the weak inversion region). For example and according to embodiments of the disclosed subject matter, t_{weak} can be 100 ns and tₛₐₘₚₗₑ can be from 1 μs to 700 μs. As such, t_{weak} can be ignored.

In some embodiments, V_{TH} can be formulated as V_{TH}(T)=V_{TH}(Tᵣₒₒₘ)+K_{VTH}(T−Tᵣₒₒₘ), where Tᵣₒₒₘ can be 300 K and K_{VTH} can be the first-order TC of V_{TH}. I_{weak}, which can be a sub-threshold leakage current of a transistor that enters the weak inversion region, can be formulated as:

$$\begin{matrix}{I}_{weak} \approx {μ}_{0} \cdot {( \frac{T}{{T}_{room}} )}^{- {k}_{a}} \cdot {C}_{ox} \cdot \frac{W}{L} \cdot ( n - 1 ) \cdot {( \frac{KT}{q} )}^{2} \cdot exp ( \frac{{V}_{GS} - {V}_{TH} ( T )}{{nV}_{T}} ) \\ \approx {μ}_{0} \cdot {C}_{ox} \cdot \frac{W}{L} \cdot ( n - 1 ) \cdot {( \frac{K}{q} )}^{2} \cdot {T}_{room}^{k} \cdot {T}^{{K}_{n}} \\ \approx {μ}_{0} \cdot {C}_{ox} \cdot \frac{W}{L} \cdot ( n - 1 ) \cdot {( \frac{K}{q} )}^{2} \cdot {T}_{room}^{{k}_{a} + {k}_{b}} \cdot {( 1 + \frac{T - {T}_{room}}{{T}_{room}} )}^{{k}_{a}} \\ \approx {μ}_{0} \cdot {C}_{ox} \cdot \frac{W}{L} \cdot ( n - 1 ) \cdot {( \frac{K}{q} )}^{2} \cdot {T}_{room}^{{k}_{a} + {k}_{b}} \cdot ( 1 + {k}_{0} \frac{T - {T}_{room}}{{T}_{room}} ) \\ \approx {μ}_{0} \cdot {C}_{ox} \cdot \frac{W}{L} \cdot ( n - 1 ) \cdot {( \frac{K}{q} )}^{2} \cdot {T}_{room}^{{k}_{a} + {k}_{b}} \cdot [ ( 1 - {k}_{0} ) + \frac{{k}_{0}}{{T}_{room}} T ] ,\end{matrix} \qquad ( 2 )$$

where kᵤ, can be the TC of mobility (μ) and k₀=−kᵤ+2. V_{GS} can be set close to V_{TH}(T) and thus, the exponential term of the sub-threshold leakage equation can become 1. Additionally or alternatively, another high-order temperature-dependent term, 1+(T−Tᵣₒₒₘ)/Tᵣₒₒₘ, can be approximated to a linear function via the Taylor series due to (T−Tᵣₒₒₘ)/Tᵣₒₒₘ being smaller than 1 for the interested temperature range. As such and as shown in equation 2, I_{weak} can become a linear function of temperature.

In some embodiments, the value of V_{SENSOR} can be formulated as:

$$\begin{matrix}{V}_{SENSOR} ( {t}_{sample} ) \approx [ {V}_{TH} ( {T}_{room} ) - {K}_{VTH} \cdot {T}_{room} - \frac{{A}_{weak} \cdot {t}_{sample}}{{C}_{sample}} ] + ( {K}_{VTE} - \frac{{K}_{weak} \cdot {t}_{sample}}{{C}_{sample}} ) \cdot T , & ( 3 ) \\ where & \\ {A}_{weak} = C \cdot ( 1 - {k}_{0} ) , {k}_{weak} = C \cdot \frac{{k}_{0}}{{T}_{room}} , C = {μ}_{0} \cdot {C}_{ox} \cdot \frac{W}{L} \cdot ( n - 1 ) \cdot {( \frac{K}{q} )}^{2} \cdot {T}_{room}^{{k}_{a} + {k}_{b}} . & \end{matrix}$$

The value of V_{SENSOR} can be a linear combination of V_{TH} and I_{weak}, which are each linear to temperature. As such, the value of V_{SENSOR} can also be linear.

In some embodiments, sampling V_{SENSOR} after the optimal time of sampling V_{SENSOR} can render invalid the assumption used in deriving equations 2 and 3 that V_{GS} is close to V_{TH}(T). As such, the exponential term of the sub-threshold leakage current equation cannot be eliminated, making the sampled value of V_{SENSOR} exhibit poor linearity. As shown in FIG. 3(a) for the purpose of illustration and not limitation, if tₛₐₘₚₗₑ>700 μs, the linearity can rapidly degrade.

In some embodiments and as shown in FIG. 3(b), sampling V_{SENSOR} just after P1 enters the weak inversion region can result in the discharge rate of V_{SENSOR} being large. As such, the value of the sampled V_{SENSOR} can be modulated by the timing variation of sampling. During the optimal time of sampling V_{SENSOR,} the discharge rate of V_{SENSOR} decreases to <30 μV/ns due to P1 being in the weak inversion region. Hence, the timing of sampling can make little, if any, impact on the value of V_{SENSOR} when sampled in the appropriate time of sampling V_{SENSOR} as embodied herein.

In some embodiments, sampling V_{SENSOR} at can maintain the TC of V_{SENSOR} across process variation. As shown in equation 3, the TC can be formulated as K_{VTH}−K_{weak}·tₛₐₘₚₗₑ/Cₛₐₘₚₗₑ, where K_{VTH} can be well-maintained across process variation as shown in FIG. 2. As such, minimizing the impact of Cₛₐₘₚₗₑ and K_{weak} can be achieved by using the smallest allowable tₛₐₘₚₗₑ value. For example, using tₛₐₘₚₗₑ=10 μs can result in K_{VTH} (−1.12 mV/° C.) being more than 50× larger than the K_{weak}·tₛₐₘₚₗₑ/Cₛₐₘₚₗₑ term.

In some embodiments, optimal tₛₐₘₚₗₑ can make the on-chip temperature sensor robust to V_{DD} noise. V_{DD} noise can modulate the precharge level and thus affect t_{weak}. However, tₛₐₘₚₗₑ can be 10 μs, which is two orders of magnitude larger than t_{weak}. As such, impact on accuracy can be negligible. FIG. 4 illustrates a graph showing an effect of sampling voltage at the sensory output node at a time after the time when the sensing PMOS transistor enters the weak inversion region. As shown in FIG. 4 for the purpose of illustration and not limitation, simulation can show the precharge-level variation of 100 mV causing a negligible error increase of <0.02° C. Similarly, t_{weak} variation induced by V_{TH} variation can also have a negligible impact on accuracy.

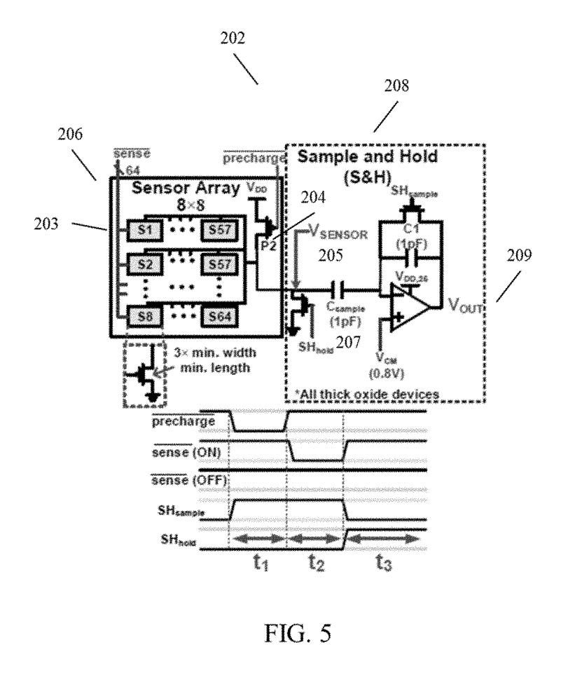

FIG. 5 illustrates a circuit diagram of another exemplary on-chip temperature sensor 202. As illustrated by the example embodiment depicted in FIG. 5, on-chip temperature sensor 202 can include an array 206 of on-chip temperature sensors 203 disposed on a chip. For example and as embodied herein, the array 206 of on-chip temperature sensors 203 can include 64 unit-size front-end circuits (S1-S64) disposed on a 65 nm chip. Each unit-size front-end circuit can be a 3× minimum-sized thick sensing PMOS transistor.

The on-chip temperature sensor 202 can also include a shared pre-charge PMOS transistor 204 (P2) electrically coupled and/or connected (e.g., by electrical wire) to the sensing PMOS transistor. Sharing the sampling capacitor 207 (Cₛₐₘₚₗₑ) and the shared pre-charge PMOS transistor 204 across the array 206 of on-chip temperature sensors 203 can result in each sensor seeing the identical load capacitance (e.g., the sum of Cₛₐₘₚₗₑ and the capacitance of all wires from Cₛₐₘₚₗₑ to the sensors) and making the TC of V_{SENSOR} (i.e., K_{VTH}−K_{weak}·t_{sample/}Cₛₐₘₚₗₑ in equation 3) the same across sensors disposed on a chip. Sharing the sampling capacitor 207 (Cₛₐₘₚₗₑ) and the shared pre-charge PMOS transistor 204 across the array 206 of on-chip temperature sensors 203 can also reduce the manufacturing variation of the Cₛₐₘₚₗₑ on accuracy and can save area.

In some embodiments, the on-chip temperature sensor 202 can also include a sample and hold circuit 208 (S&H) electrically coupled and/or connected (e.g., by electrical wire) to the shared pre-charge PMOS transistor 204 and the array 203 of sensing PMOS transistors. As shown in FIG. 5 for the purpose of illustration and not limitation, the sensory output (V_{SENSOR}) node 205 can be pre-charged by P2 to V_{DD} during t₁. One of the unit-sized front-end circuits can be selected and can discharge V_{SENSOR} 205 during t₂. The sample and hold circuit 208 can be in sampling mode during the t₁+t₂ period. The sample and hold circuit can then measure V_{SENSOR} 205 on V_{OUT} 209 in the hold mode. V_{OUT} 209, which can be V_{CM} (0.8V) V_{SENSOR} (tₛₐₘₚₗₑ), can be digitized by an analog-to-digital converter (ADC) (e.g., 16 bit, ±5V). For example, the analog-to-digital converter can be an off-chip analog-to-digital converter. Additionally or alternatively, the sensor front-end circuits not selected can experience negative V_{GS} and thus can have negligible impact on V_{SENSOR} (tₛₐₘₚₗₑ).

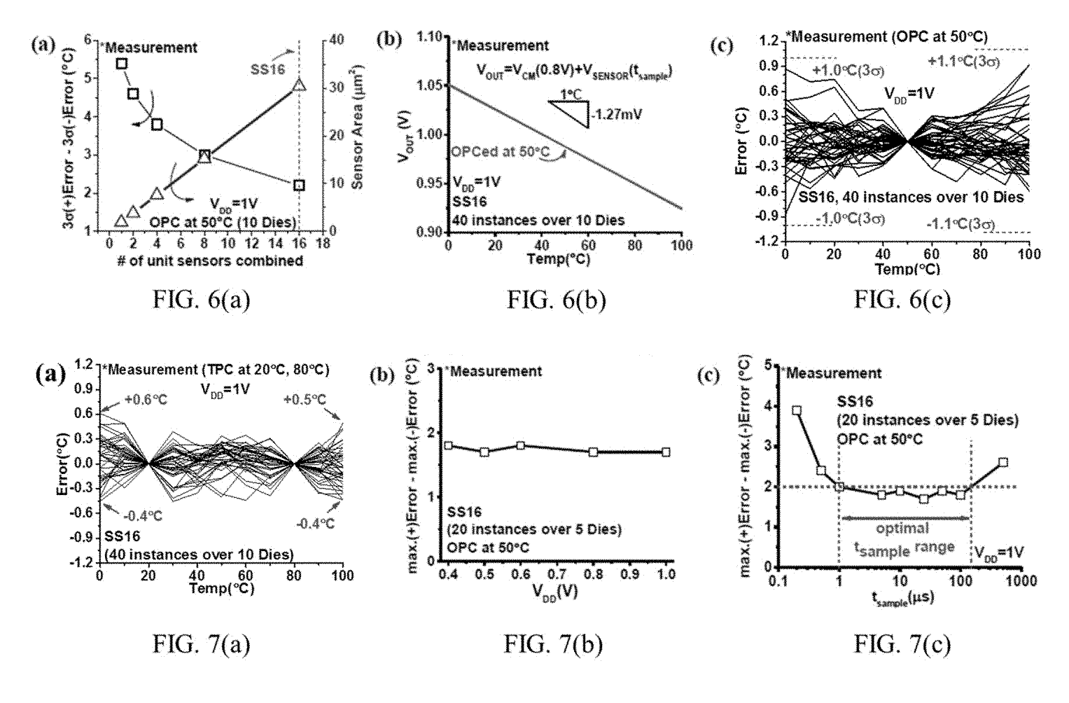

Measurements can exhibit robustness from 40 sensor front-end circuits across 10 chips. In some embodiments, multiple unit-size front-end circuits can be combined and measured. FIG. 6(a) illustrates a graph showing measurements results of 3σerrors of multiply combined on-chip temperature sensors. As shown in FIG. 6(a) for the purpose of illustration and not limitation, 16 unit-size sensors combined to form a sensor front-end circuit (SS16) can achieve a 3σerror of ±1.1° C. after OPC at 50° C.

FIG. 6(b) illustrates a graph showing measurements results of output voltage from dies including on-chip temperature sensors after temperature point calibration. As shown in FIG. 6(b) for the purpose of illustration and not limitation, the average TC of the V_{OUTs} of the 40 SS16s after OPC can be 1.27 mV/° C.

FIG. 6(c) illustrates a graph showing measurements results of errors of dies including on-chip temperature sensors after temperature point calibration. As shown in FIG. 6(c) for the purpose of illustration and not limitation, the V_{OUTs} can be translated into temperatures and errors after OPC can be found. The footprint of the SS16 can be 30.1 μm².

FIG. 7(a) illustrates a graph showing measurements results of errors of dies including on-chip temperature sensors after temperature point calibration. As shown in FIG. 7(a) for the purpose of illustration and not limitation, two temperature point calibration (TPC) at 20° C. and 80° C. can further reduce error to −0.41/+0.6° C.

Voltage scalability of the sensors can also be measured. FIG. 7(b) illustrates a graph showing measurements results of worst-case errors of dies including on-chip temperature sensors across supply voltage after temperature point calibration. For example, worst-case errors can be max.(+)error−max.(−)error . As shown in FIG. 7(b) for the purpose of illustration and not limitation, measurements across 20 instances across 5 chips show that the worst-case errorsafter OPC can be nearly constant to be about 1.8° C. across V_{DDs}.

Impact of tₛₐₘₚₗₑ on accuracy can also be measured. FIG. 7(e) illustrates a graph showing measurements results of worst-case errors of dies including on-chip temperature sensors across time. As shown in FIG. 7(c) for the purpose of illustration and not limitation, the range of tₛₐₘₚₗₑ which makes the worst-case error <2° C. can be measured to be from about 1 μs to about 100 μs.

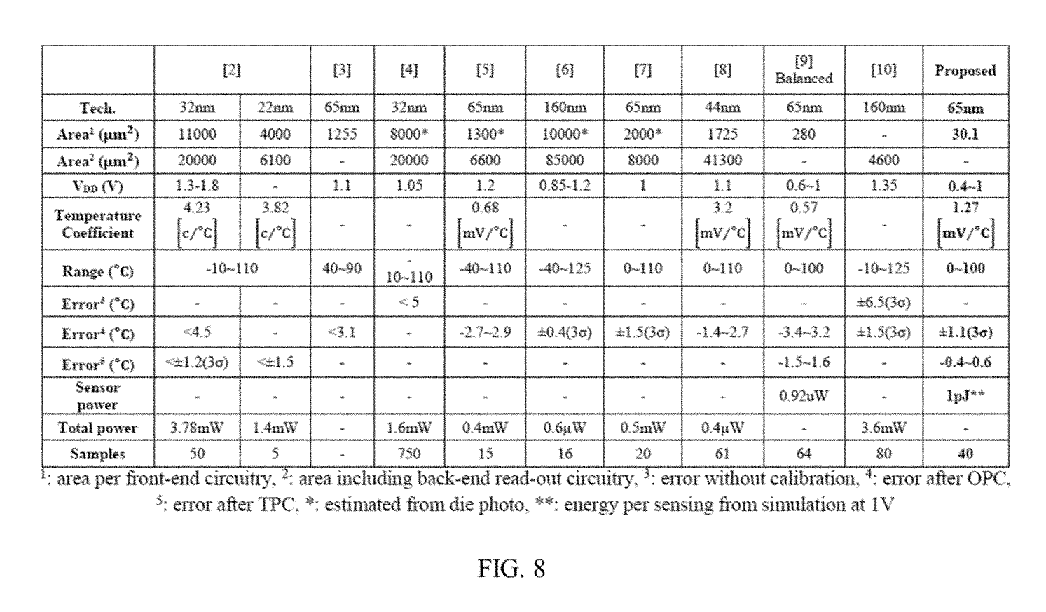

FIG. 8 illustrates an exemplary table showing robustness results, in accordance with one or more embodiments. Measurement values and performance metrics (e.g., technology node, area per front-end circuitry, V_{DD}, temperature coefficient, temperature range, error after OPC, error after TPC, sensor power, and samples) for the disclosed on-chip temperature sensor are listed against such measurement values and metrics for other on-chip temperature sensors.

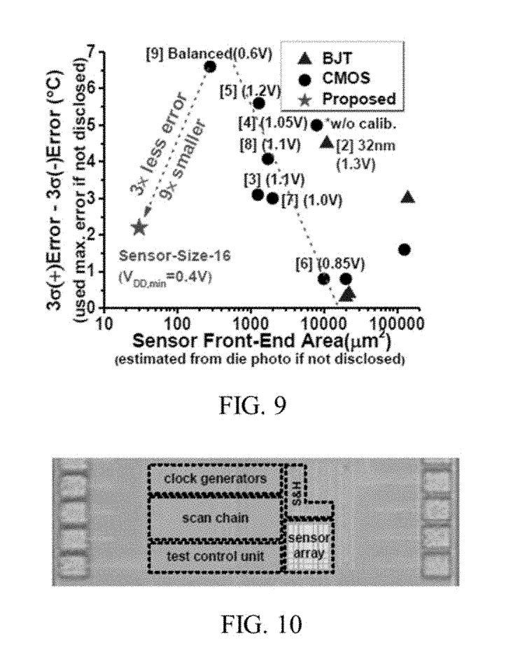

FIG. 9 illustrates a graph showing robustness results. FIG. 10 illustrates an exemplary diagram of a die including on-chip temperature sensors. As shown in FIGS. 9 and 10 for the purpose of illustration and not limitation, the disclosed on-chip temperature sensor can have a footprint of 30.1 μm2, which can be 9× smaller than previously designed footprints having comparable robustness. According to an exemplary embodiment, the disclosed on-chip temperature sensor can have an an error of <±1.1° C. (3σ) across 40 dies, which can be 3×more accurate than other sensors. Additionally, or altneratively, as compared to certain other sensors, the disclosed on-chip temperature sensor can have a voltage scalability of 0.4V, which can be 0.2V lower than certain existing low-voltage designs.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulates and/or transforms data represented as physical, such as electronic, quantities within the computing system's registers and/or memories into other data similarly represented as physical quantities within the computing system's memories, registers or other such information storage, transmission or display devices.

Although one or more embodiments have been described herein in some detail for clarity of understanding, it should be recognized that certain changes and modifications can be made without departing from the spirit of the disclosure. Features of certain embodiments can be combined with features of other embodiments; thus certain embodiments can be combinations of features of multiple embodiments. The embodiments described herein can employ various computer-implemented operations involving data stored in computer systems. For example, these operations can require physical manipulation of physical quantities—usually, though not necessarily, these quantities can take the form of electrical or magnetic signals, where they or representations of them are capable of being stored, transferred, combined, compared, or otherwise manipulated. Further, such manipulations are often referred to in terms, such as producing, yielding, identifying, determining, or comparing. Any operations described herein that form part of one or more embodiments of the disclosure can be useful machine operations. In addition, one or more embodiments of the disclosure also relate to a device or an apparatus for performing these operations. The apparatus can be specially constructed for specific required purposes, or it can be a general purpose computer selectively activated or configured by a computer program stored in the computer. In particular, various general purpose machines can be used with computer programs written in accordance with the teachings herein, or it can be more convenient to construct a more specialized apparatus to perform the required operations.

Although one or more embodiments of the present disclosure have been described in some detail for clarity of understanding, it will be apparent that certain changes and modifications can be made within the scope of the claims. Accordingly, the described embodiments are to be considered as illustrative and not restrictive, and the scope of the claims is not to be limited to details given herein, but can be modified within the scope and equivalents of the claims. In the claims, elements do not imply any particular order of operation, unless explicitly stated in the claims.

Many variations, modifications, additions, and improvements can be made. Plural instances can be provided for components, operations or structures described herein as a single instance. Boundaries between various components, operations and data stores are somewhat arbitrary, and particular operations are illustrated in the context of specific illustrative configurations. Other allocations of functionality are envisioned and can fall within the scope of the disclosure(s). In general, structures and functionality presented as separate components in exemplary configurations can be implemented as a combined structure or component. Similarly, structures and functionality presented as a single component can be implemented as separate components. These and other variations, modifications, additions, and improvements can fall within the scope of the appended claim(s).

What is claimed is:

1. A system for measuring a temperature dependency of a threshold voltage, comprising:
a shared pre-charge P-type metal-oxide-semiconductor (PMOS) transistor, configured to pre-charge an output node to a supply voltage; and
a sensing PMOS transistor, electrically coupled to the shared pre-charge PMOS transistor, configured to discharge the output node to a first voltage at or near the threshold voltage of the sensing PMOS transistor and measure a second voltage at the output node.

2. A system of claim 1, wherein the sensing PMOS transistor is configured to enter a weak inversion region once the sensing PMOS transistor discharges the output node to the first voltage.

3. A system of claim 1, wherein a gate source voltage of the sensing PMOS transistor is configured to be set at or near the threshold voltage.

4. A system of claim 1, wherein the sensing PMOS transistor is configured to measure the second voltage at a time after the sensing PMOS transistor discharges the output node.

5. A system for measuring a temperature dependency of a threshold voltage, comprising:
a shared pre-charge P-type metal-oxide-semiconductor (PMOS) transistor, configured to pre-charge an output node to a supply voltage; and
an array of sensing PMOS transistors, electrically coupled to the shared pre-charge PMOS transistor, each configured to discharge the output node to a first voltage at or near the threshold voltage of the sensing PMOS transistor and measure a second voltage at the output node.

6. The system of claim 5, further comprising a sample and hold circuit, electrically coupled to the shared pre-charge PMOS transistor and the array of sensing PMOS transistors, configured to measure a third voltage at the output node.

7. The system of claim 6, further comprising an analog-to-digital convertor, configured to digitize the third voltage.

8. A method for measuring a termperature dependency of a threshold voltage, comprising:
pre-charging an output node to a supply voltage using a shared pre-charge P-type metal-oxide-semiconductor (PMOS) transistor; and
measuring a second voltage at the output node, using a sensing PMOS transistor, by discharging the output node to a first voltage at or near the threshold voltage of the sensing PMOS transistor.

9. The method of claim 8, further comprising measuring a third voltage at the output node using a sample and hold circuit.

10. The method of claim 9, further comprising digitizing the third voltage using an analog-to-digital converter.

11. A method of claim 8, wherein the sensing PMOS transistor enters a weak inversion region upon the discharging the output node.

12. A method of claim 8, further comprising setting a gate source voltage of the sensing PMOS transistor at or near the threshold voltage.

13. A method of claim 8, wherein the measuring a second voltage is at a time after the discharging the output node.
